(19) United States
(12) Patent Application Publication
(10) Pub. No.: US 2018/0097166 A1
(43) Pub. Date: Apr. 5, 2018

(54) Doped N-Type Polycrystalline Sn-Se-S and Methods of Manufacture

(71) Applicant: University of Houston System, Houston, TX (US)

(72) Inventors: Zhifeng Ren, Pearland, TX (US); Qian Zhang, Houston, TX (US); Eyob Kebede Chere, Houston, TX (US)

(73) Assignee: University of Houston System, Houston, TX (US)

(21) Appl. No.: 15/559,929

(22) PCT Filed: Dec. 10, 2015
(86) PCT No.: PCT/US2015/065127

§ 371 Date: Sep. 20, 2017

Related U.S. Application Data
(60) Provisional application No. 62/138,084, filed on Mar. 25, 2015.

(51) Int. Cl. H01L 35/16; H01L 35/34

(52) U.S. Cl. CPC H01L 35/16; C01B 19/002; H01L 35/34

(57) ABSTRACT

Disclosed is a thermoelectric material according to various SSnSe-based formulas, and the systems and methods of manufacturing the thermoelectric, high performance material by hot pressing materials according to various formulas in order to obtain a figure of merit (ZT) suitable for thermoelectric applications at high (above 600K) temperatures. A disclosed method comprises hot-pressing a powder that comprises Sn and Se in a predetermined direction to form a pressed component, wherein the pressed component comprises a ZT value of at least 0.8 above about 750 K.

### CROSS-REFERENCE TO RELATED APPLICATIONS

This application is a 35 U.S.C. § 371 national stage application of PCT/US2015/065127 filed Dec. 10, 2015, and entitled “Doped N-Type Polycrystalline Sn—Se—S and Methods of Manufacture”, which claims priority to U.S. Provisional Application No. 62/138,084, “Doped N-Type Polycrystalline SnSe₁₋ₓSₓ And Methods of Manufacture,” filed Mar. 25, 2015, and incorporated herein by reference in its entirety for all purposes.

### STATEMENT REGARDING FEDERALLY-SPONSORED RESEARCH OR DEVELOPMENT

This work is supported by “Solid State Solar Thermal Energy Conversion Center (S³TEC)”, an Energy Frontier Research Center funded by the U.S. Department of Energy, Office of Science, Office of Basic Energy Science under award number DE-SC0001299

### BACKGROUND

Over the past decades, thermoelectric materials have been extensively studied for potentially broad applications in refrigeration, waste heat recovery, solar energy conversion, etc. The efficiency of thermoelectric devices is governed by the materials' dimensionless figure of merit ZT=(S²σ/κ)T, where S is the Seebeck, σ is the electrical conductivity, T is the absolute temperature, and κ is the thermal conductivity, respectively.

### BRIEF SUMMARY OF THE DISCLOSURE

In an embodiment, a method of manufacturing a thermoelectric material comprising: hot-pressing a powder in a predetermined direction to form a pressed component, wherein the powder comprises Sn and Se, wherein the pressed component comprises a ZT value of at least 0.8 above about 750 K.

In an embodiment, a thermoelectric device comprising: a thermoelectric material according to a formula SnSe₁₋ₓIₓ, wherein the thermoelectric material comprises a ZT of at least 0.8 at about 750 K.

In another embodiment, a thermoelectric device comprising: a thermoelectric material according to the formula SnSe_{1-x-y}S_{y}Iₓ wherein the thermoelectric material comprises a ZT of at least 0.8 at above about 750 K.

### BRIEF DESCRIPTION OF THE DRAWINGS

For a detailed description of the exemplary embodiments disclosed herein, reference will now be made to the accompanying drawings in which:

FIG. 1A illustrates the x-ray diffraction (XRD) pattern taken in the direction of the plane parallel to the hot pressing direction of samples fabricated according to certain embodiments of the present disclosure.

FIG. 1B illustrates the XRD pattern taken in the direction perpendicular to the hot pressing direction of samples fabricated according to certain embodiments of the present disclosure.

FIGS. 2A and 2B are SEM images of fracture surfaces of thermoelectric materials fabricated according to certain embodiments of the present disclosure.

FIG. 3 is a graph that illustrates the temperature dependence of specific heat for SnSe_{1-y}S_{y}.

FIGS. 4A-4F are graphs which illustrate the temperature dependence of various thermoelectric properties measured along the hot pressing direction in samples of doped SnSe₁₋ₓIₓ fabricated according to certain embodiments of the present disclosure as compared to undoped SnSe.

FIGS. 5A and 5B illustrate thermoelectric properties for samples of SnSe₁₋ₓIₓ fabricated according to embodiments of the present disclosure.

FIGS. 6A-6F illustrate thermoelectric properties for samples of SnSe₁₋ₓIₓ fabricated according to embodiments of the present disclosure in both directions parallel and perpendicular to the hot-pressing direction.

FIGS. 7A and 7B are XRD patterns of bulk samples SnSe_{0.97-y}S_{y}I_{0.03} fabricated according to certain embodiments of the present disclosure, taken along the hot pressing direction and perpendicular to the hot pressing direction.

FIGS. 8A-8F illustrate thermoelectric properties for samples of SnSe₁₋ₓIₓ fabricated according to embodiments of the present disclosure in both directions parallel and perpendicular to the hot-pressing direction.

FIG. 9 illustrates optical absorption spectra and band gaps for undoped SnSe, SnSe_{0.97}I_{0.03}, SnSe_{0.87}S_{0.1}I_{0.03}, and SnSe_{0.67}S_{0.3}I_{0.03}.

FIG. 10 illustrates a flow chart of a method of fabricating SnSeI materials according to certain embodiments of the present disclosure.

### DETAILED DESCRIPTION OF THE DISCLOSED EXEMPLARY EMBODIMENTS

The following discussion is directed to various exemplary embodiments. However, one of ordinary skill in the art will understand that the examples disclosed herein have broad application, and that the discussion of any embodiment is meant only to be exemplary of that embodiment, and not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

In the following discussion and in the claims, the terms “including” and “comprising” are used in an open-ended fashion, and thus should be interpreted to mean “including, but not limited to . . . .”

Thermoelectric (TE) materials are useful for power generation and/or cooling applications because of the electric voltage that develops when a temperature differential is created across the material. TE cooling systems operate on the principal that a loop (circuit) of at least two dissimilar materials can pass current, absorbing heat at one end of the junction between the materials and releasing heat at the other end of the junction, and TE power generators enable the direct conversion from heat to electricity. As such, TE materials may be fabricated so that, when heat is applied to a portion of the TE material, the electrons migrate from the hot end towards a “cold” end, e.g., a portion of the TE material where heat is not being applied. The electrical current created when the electrons migrate may be harnessed for power, and the amount of electrical current (and resultant power generated) increases with an increasing temperature difference from the hot side of the TE material to the cold side. However, when a TE material is heated up, if it is heated for a long enough time period, held at a temperature over a time period, and/or heated to a high enough temperature, the cold side may actually heat up, so the thermoelectric devices in which the TE materials are employed may also use various methods to pull heat away from the cold side.

In an embodiment, materials for thermoelectric generators are fabricated to possess high dimensionless figure of merit ZT=[S²σ/(□ₑ₊□_{L})]T, where S, σ, □ₑ, □_{L}, and T are the Seebeck coefficient, electrical conductivity, electronic thermal conductivity, lattice thermal conductivity, and absolute temperature, respectively. The thermoelectric effect is a combination of phenomenon including the Seebeck effect, Peltier effect, and Thomson effect. The Seebeck coefficient is associated with the Seebeck effect, which is the name of the effect observed when an electromagnetic effect is created when a structure (loop) is heated on one side. The Peltier effect is the term used to explain heating or cooling at a junction between two different TE materials when a current is generated in a circuit or other loop comprising the two different TE materials. The Thomson effect occurs when a Seebeck coefficient is not constant at a temperature (depending upon the TE material), so when an electric current is passed through a circuit of a single TE material that has a temperature gradient along its length, heat may be absorbed, and the temperature difference may be redistributed along the length when the current is applied. Thus, higher ZT values for TE materials across a variety of temperature ranges may continue to become increasingly valuable for applications at least across the fields of TE power generation and cooling. “Studies on Thermoelectric Properties of n-type Polycrystalline SnSe₁₋ₓSₓ by Iodine Doping,” published in Advanced Materials Review Apr. 22, 2015, is incorporated herein in its entirety by this reference.

Thermoelectric materials may comprise n-type and/or p-type materials, which may be referred to as alloys or legs, depending upon how the TE materials are to be employed. N-type materials may comprise materials that have lattice atoms replaced with five valence electrons such as Group 5 elements. These impurities create one excess electron in the lattices, and the Group 5 atoms may be referred to as donors. The “n” stands for “negative,” since donor impurities donate negatively charged electrons to the lattice. P-type materials are referred to as such because the semiconductor is doped with an “acceptor,” such as Group 3 elements. The acceptor donates excess holes which are considered to be positively charged, and the material is referred to as a p-type (positive) TE material. It is understood that both n- and p-type TE materials are electrically neutral, that is, the materials comprise equal numbers of protons and electrons.

Previously developed n-type tin chalcogenide alloys may not be available to be employed in thermoelectric applications. As discussed herein, I-doped n-type SnSe was fabricated having a ZT, among other thermoelectric properties, that may be desirable for thermoelectric applications. With increasing content of iodine, the carrier concentration changed from 2.3×10¹⁷ cm⁻³ (p-type) to 5.0×10¹⁵ cm⁻³ (n-type) then to 2.0×10¹⁷ cm⁻³ (n-type). By alloying with SnS, the lowered thermal conductivity and enhanced Seebeck coefficient contributed to a highest ZT of ˜1.0 at about 773 K for SnS_{0.1}Se_{0.87}I_{0.03} polycrystals measured along the hot-pressing direction.

Using the systems and methods discussed herein, a plurality of samples of anisotropic I-doped n-type SnSe polycrystals were fabricated, these samples exhibited a peak ZT of about 0.8 at about 773 K, as measured along the hot-pressing direction. Since SnS and SnSe form a continuous series of solid solution, by alloying with SnS, the thermal conductivity decreased and the Seebeck coefficient increased, leading to an increased peak ZT of ˜1.0 at about 773 K for SnS_{0.1}Se_{0.87}I_{0.03} polycrystals measured also along the hot-pressing direction. I-doped n-type SnSe polycrystal was successfully prepared by melting and hot pressing. The electrons from iodine doping first decreased the hole carrier concentration and then increased the electron carrier concentration to ˜2×10¹⁷ cm⁻³ in SnSe_{0.96}I_{0.04}. ZT of ˜0.8 at about 773 K was obtained due to the intrinsic ultralow thermal conductivity in SnSe_{0.97}I_{0.03}. A higher ZT of ˜1.0 at about 773 K was achieved by alloying 10 atm. % SnS with 3 atm. % I-doping due to even lower thermal conductivity. As such, the doping of SnSe_{1-y}S_{y} compounds was performed as discussed in certain embodiments of the present disclosure in order to achieve a ZT for high-temperature (over about 600K) applications.

Fabrication of Exemplary TE Materials

In an exemplary embodiment, n-type iodine-doped polycrystalline samples of SnSe, SnSe_{0.9}S_{0.1}, and SnSe_{0.7}S_{0.3} were prepared by melting the raw materials (Sn granules, 99.9%; Se granules, 99.99%; S pieces, 99.999%; and SnI₂ beads, 99.99%) in the double sealed quartz tubes. The raw materials were slowly (100° C. h⁻¹) raised to 920° C. and kept for 6 h, then slowly (100° C. h⁻¹) cooled to 600° C. and maintained at that temperature for 70 h, finally slowly (100° C. h⁻¹) cooled to room temperature. The resulting ingots were cleaned and broken down by a high-energy ball mill SPEX 8000D (SPEX Sample Prep.) for 1 min to get the powder. The milled powder was loaded into the half-inch die and hot pressed by alternating current (ac-HP) press at 600° C. for 7 min under 50 MPa to get a 14 mm rod.

Considering the anisotropy of SnSe and SnS, all the samples were cut from both parallel and perpendicular to the pressing direction and measured along both directions. X-ray diffraction spectra analysis was conducted on a PANalytical multipurpose diffractometer with an X'celerator detector (PANalytical X'Pert Pro) from different directions of the anisotropic sample. The lattice parameters were calculated by the Rietveld refinement method. The microstructures were investigated by a scanning electron microscope (SEM, LEO 1525). The chemical composition was analyzed on an energy-dispersive X-ray (EDX) spectrometer attached to SEM (JEOL 6330F). Room temperature optical diffuse reflectance spectra of the powder were obtained on a UV-Vis-NIR Spectrophotometer (Cary 5000) equipped with a polytetrafluoroethylene (PTFE) integrating sphere. Absorption data were calculated from reflectance data using the Kubelka-Munk function. The optical band gaps were derived from absorption versus energy plots. The electrical resistivity (p) and Seebeck coefficient (S) were simultaneously obtained on a commercial system (ULVAC ZEM-3) from room temperature to 500° C. The thermal conductivity was calculated using □=DαCₚ, where D is volumetric density determined by the Archimedes method, α the thermal diffusivity obtained on a laser flash apparatus (Netzsch LFA 457) for an half inch disk with thickness of <1.5 mm, and Cₚ the specific heat measured on a differential scanning calorimetry thermal analyzer (Netzsch DSC 404 C). The Hall Coefficient R_{H} at room temperature was measured using a PPMS (Quantum Design Physical Properties Measurement System) with a magnetic field of −3 T and 3 T and an electrical current of 8 mA. The Hall carrier concentration n_{H} was calculated using n_{H}=1/(eR_{H}). The uncertainty for the electrical conductivity is 3%, the Seebeck coefficient 5%, the thermal conductivity 7% (comprising uncertainties of 4% for the thermal diffusivity, 5% for the specific heat, and 3% for the density), so the combined uncertainty for the power factor is 10% and that for ZT value is 12%.

Post-Fabrication Characteristization

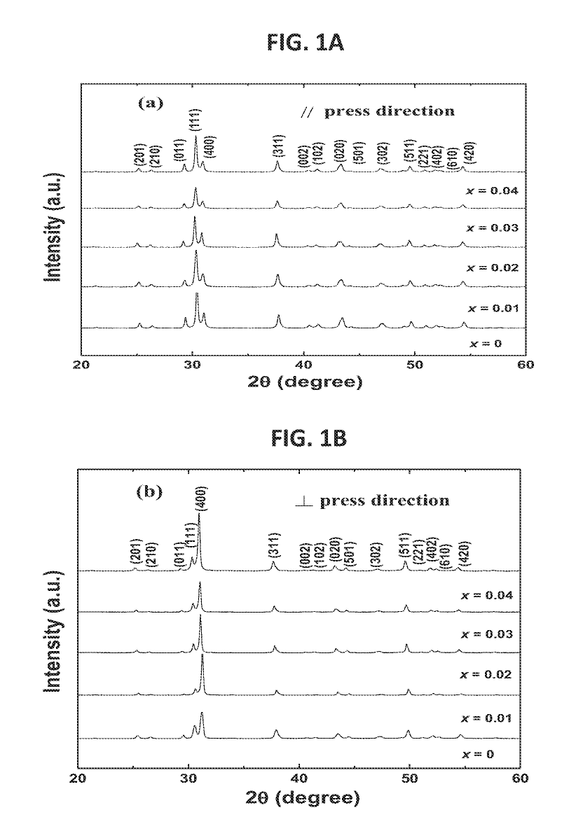

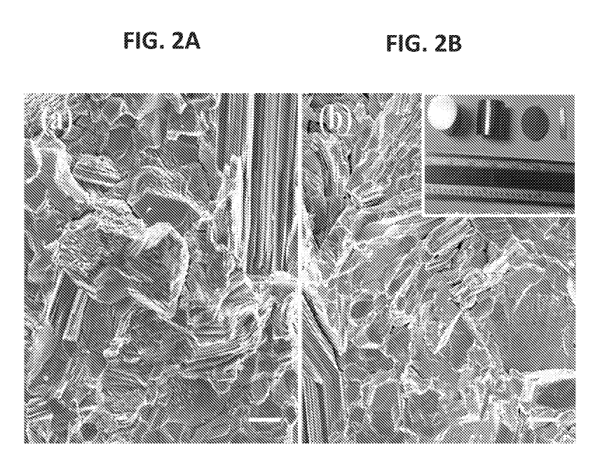

Referring to FIGS. 1A and 1B, FIG. 1A illustrates an x-ray diffraction (XRD) pattern taken in the direction of the plane parallel to the hot pressing direction, and FIG. 1B illustrates the XRD pattern taken in the direction perpendicular to the hot pressing direction. Because the TE materials may be employed in applications where there is a temperature gradient (e.g., a hot side and a cold side) created across the TE materials, the properties of a material may vary based upon the direction in which the current is applied, so measurements were obtained both parallel and perpendicular to the hot-pressing direction of TE samples for various TE properties as discussed herein. SnSe crystallizes in a layered structure with the orthorhombic Pnma space group (PDF #32-1382 from a standard XRD database) at room temperature. The calculated lattice parameters for undoped SnSe (a=11.48 Å, b=4.15 Å, and c=4.43 Å) were consistent with the expected lattice parameters for this fabricated material. The difference in diffraction intensity in (400) and (111) planes as shown between FIGS. 1A and 1B indicates the existence of anisotropy of the samples in agreement with the microstructure shown in the SEM image FIG. 2A discussed herein. All the peaks were indexed in FIGS. 1A and 1B without any impurities in spite of the high concentration of iodine.

Referring now to FIGS. 2A and 2B, FIG. A is an SEM fracture image of of I-doped SnSe_{0.97}I_{0.03} (a) on bulk samples perpendicular to the hot pressing direction. FIG. 2B is an SEM image of a fractured surface parallel to the hot pressing direction. The scale bar is 10 □m in both FIGS. 2A and 2B, and the inset image 202 in FIG. 2B illustrates a hot-pressed disc similar to the disc used for the images in FIGS. 2A and 2B.

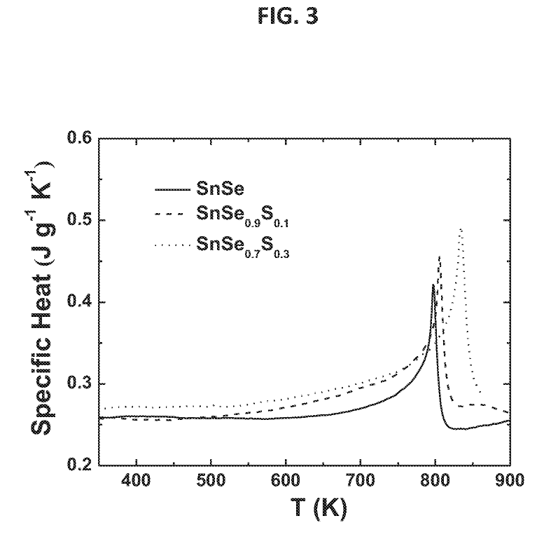

Referring now to FIG. 3, the temperature dependence of specific heat (Cᵣ) for SnSe_{1-y}S_{y} (y=0, 0.1, and 0.3). The Cₚ of the undoped SnSe, SnSe_{0.9}Se_{0.1}, and SnSe_{0.7}Se_{0.3} were used for the calculation of the total thermal conductivity of I-doped SnSe, SnSe_{0.9}Se_{0.1}, and SnSe_{0.7}Se_{0.3}, respectively as discussed herein. The electrical conductivity of SnSe is much lower than those of the traditional state-of-the-art thermoelectric materials in spite of the single crystallization. The very high ZT of SnSe is attributed to the ultralow thermal conductivity due to the intrinsically high anharmonicity of the chemical bonds. Polycrystal SnSe has even lower electrical conductivity compared with single crystal SnSe. The Hall carrier concentration can be increased from ˜2×10¹⁷ cm⁻³ to ˜9×10¹⁸ Om⁻³ by Ag doping. However, the electrical conductivity is still low because of the low hole mobility in polycrystals. In some embodiments, by doping with iodine, n-type SnSe polycrystals were first prepared by melting and hot pressing.

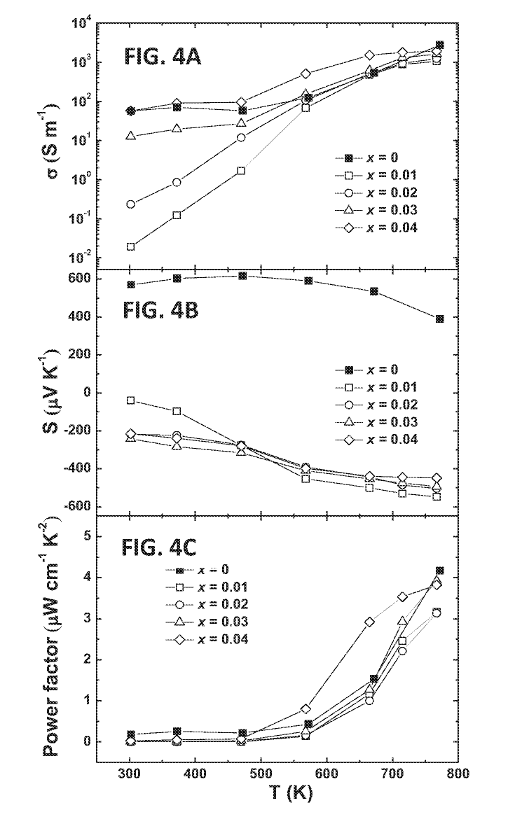

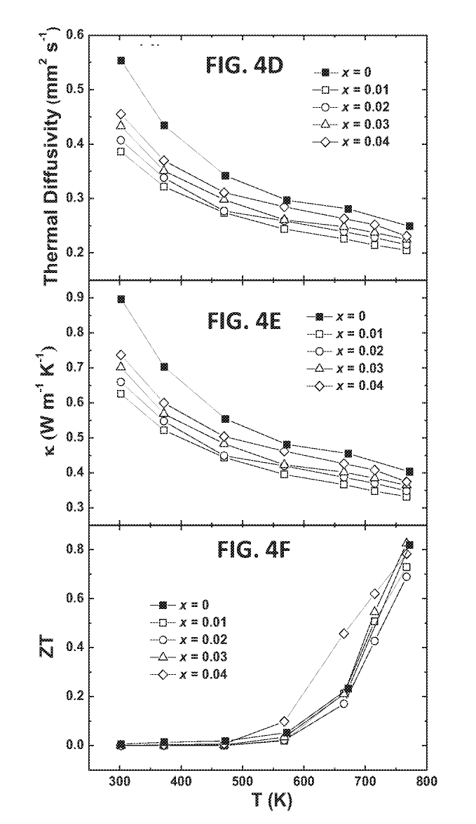

Turning now to FIGS. 4A-4F which illustrate the temperature dependence of electrical conductivity (FIG. 4A), Seebeck coefficient (FIG. 4B), power factor (FIG. 4C), thermal diffusivity (FIG. 4D), total thermal conductivity (FIG. 4E) and ZT (f) of all doped SnSe₁₋ₓIₓ (x=0.01, 0.02, 0.03, and 0.04) compared with undoped SnSe measured along the hot pressing direction. All the electrical conductivities increased with increasing temperature, showing typical semiconductor behavior. It has been reported that nominal stoichiometric SnSe shows p-type intrinsic behavior, like the undoped results in FIGS. 4A-4F. But actually it has real composition around SnSe_{0.86} with Se defect due to the evaporation of Se (see table 1). In an embodiment, up to 5 atm. % of extra Se was added during sample preparation. The resulting compound still showed as p-type with negligible carrier density change and became n-type with 5 atm. % extra Sn. FIG. 4D illustrates that the thermal diffusivity for the samples decreases with increasing temperature, with the x=0 sample having the highest thermal diffusivity across the measured temperature range, and the x=0.01 sample having the lowest, with the x=0.04 sample having a substantially similar thermal diffusivity to the x=0.01 sample at about 475K.

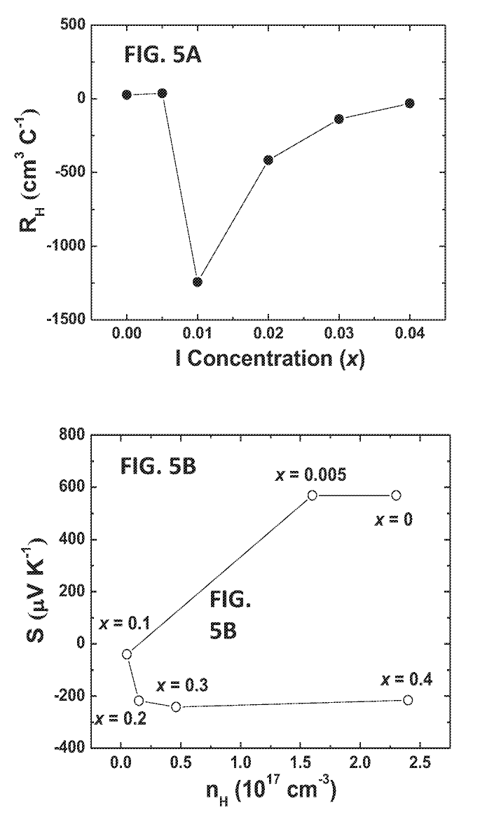

Iodine doping changed the conductive type from p-type to n-type across the temperature range (about 300K to about 800K) when x≧0.01, which was confirmed by both the measured Seebeck coefficients (FIG. 4B) and Hall coefficients (FIG. 5A). The electrical conductivity as shown in FIG. 4A initially decreased (x≦0.01) then increased (x≧0.01) with increasing content of iodine, but the value is still as low as the undoped SnSe when x=0.04. Thus in spite of the high Seebeck coefficient shown in FIG. 4B, the power factor is only ˜4 μW cm⁻¹K⁻² at about 800 K as illustrated in FIG. 4C. Normally, the Seebeck coefficient decreases with increasing carrier concentration.

Referring to FIGS. 5A and 5B, FIG. 5A illustrates the relationship between the room temperature Hall coefficient (R_{H}) and the iodine concentration (x) for SnSe₁₋ₓIₓ (x=0, 0.005, 0.01, 0.02, 0.03, and 0.04). The Pisarenko relation for SnSe₁₋ₓIₓ in FIG. 5B illustrates the negative Seebeck coefficient increased with increasing electron carrier concentration when x<0.03 due to the relatively high density of minority carriers when the electron carrier concentration is low.

Considering the low electronic thermal conductivity (□ₑ=LσT, where L is the Lorenz number), the lattice thermal conductivity (□_{L}=□ₜₒₜₐₗ−□ₑ) is close to the total thermal conductivity as shown in FIG. 4E. The high ZT of about 0.8 at about 773 K as shown in FIG. 4F may be a benefit of this very low intrinsic thermal conductivity. FIG. 4F also illustrates that all of the doped samples exhibit a ZT of at least about 0.7 above about 700K.

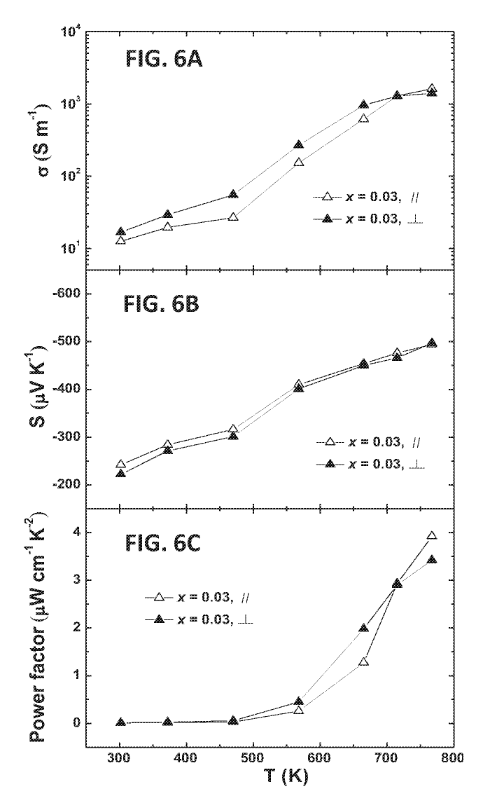

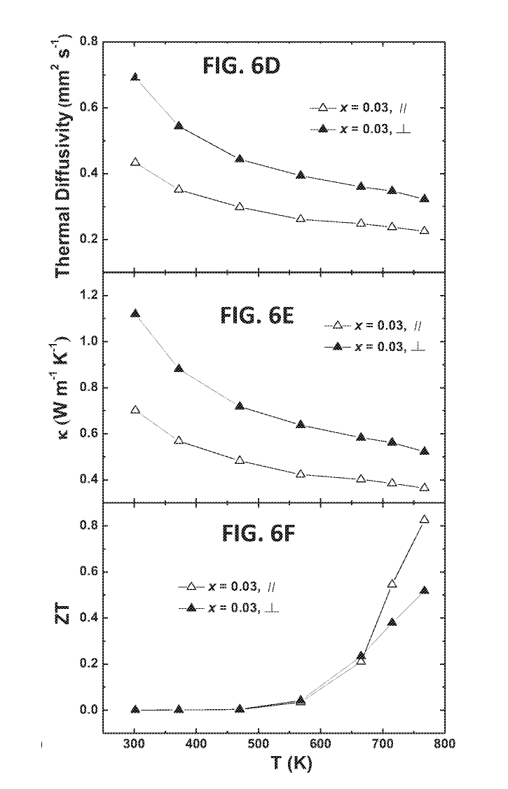

Turning now to FIGS. 6A-6F which illustrate the temperature dependence of electrical conductivity (FIG. 6A), Seebeck coefficient (FIG. 6B), power factor (FIG. 6C), thermal diffusivity (FIG. 6D), total thermal conductivity (FIG. 6E) and ZT (FIG. 6F), respectively of all doped SnSe₁₋ₓ Iₓ (x=0.01, 0.02, 0.03, and 0.04) as compared to the undoped SnSe. The properties in FIGS. 6A-6F were measured both perpendicular (⊥) and parallel (//) to the hot pressing direction. The electrical conductivity in FIG. 6A and the thermal conductivity in FIG. 6E measured from perpendicular (solid/filled symbols) to the hot pressing direction were higher than those measured from parallel (open symbols) to the hot pressing direction. As shown in FIG. 6B, the Seebeck coefficient is almost the same when measured in each of the directions, i.e. when measured parallel to the hot pressing direction and measured perpendicular to the hot pressing direction. The power factor, as shown in FIG. 6C, is substantially similar for both samples from about 300K to about 475K, then the value when measured perpendicular to the hot pressing direction increases until about 725K when the power factor for the sample measured parallel to the hot-pressing direction becomes greater than that measured perpendicular to the hot pressing direction. FIG. 6F illustrates that the ZT is higher when measured parallel to the hot pressing direction than when measured perpendicular to it, and FIG. 6D illustrates that the thermal diffusivity is higher across the measured temperature range when measured in the direction perpendicular to the hot pressing direction.

TABLE 1
Room temperature real composition, density, Hall carrier concentration, electrical
conductivity, and total thermal conductivity for SnSe₁₋ₓIₓ and SnSe_{0.97-y}S_{y}I_{0.03}.

| | | | n_{H} | | |
|---|---|---|---|---|---|
| Nominal | | Density | (10¹⁷ | □ | □ (W m⁻¹ |
| Comp. | Real Comp. | (g cm⁻³) | cm⁻³) | (S m⁻¹) | K⁻¹) |
| SnSe | SnSe_{0.86} | 6.05 | 2.3 | 56.5 | 0.90 |
| SnSe_{0.995}I_{0.005} | SnSe_{0.891}I_{0.006} | 5.90 | 1.6 | 0.22 | 0.65 |
| SnSe_{0.99}I_{0.01} | SnSe_{0.883}I_{0.013} | 5.87 | 0.05 | 0.02 | 0.63 |
| SnSe_{0.98}I_{0.02} | SnSe_{0.856}I_{0.021} | 5.84 | 0.15 | 0.23 | 0.66 |
| SnSe_{0.97}I_{0.03} | SnSe_{0.884}I_{0.034} | 5.81 | 0.46 | 12.5 | 0.70 |
| SnSe_{0.96}I_{0.04} | SnSe_{0.873}I_{0.04} | 5.80 | 2.4 | 56.8 | 0.74 |
| SnSe_{0.87}S_{0.1}I_{0.03} | SnSe_{0.88}S_{0.07}I_{0.04} | 5.75 | 0.38 | 15.8 | 0.72 |
| SnSe_{0.67}S_{0.3}I_{0.03} | SnSe_{0.68}S_{0.29}I_{0.03} | 5.61 | 0.25 | 7.19 | 0.49 |

SnS also crystalizes in a layered structure with orthorhombic Pbmn space group (PDF #39-0354) at room temperature. SnS undergoes the structure transition from orthorhombic to tetragonal at about 858 K. The alloying effect of SnS into SnSe was also studied to see whether further reduction on thermal conductivity is possible.

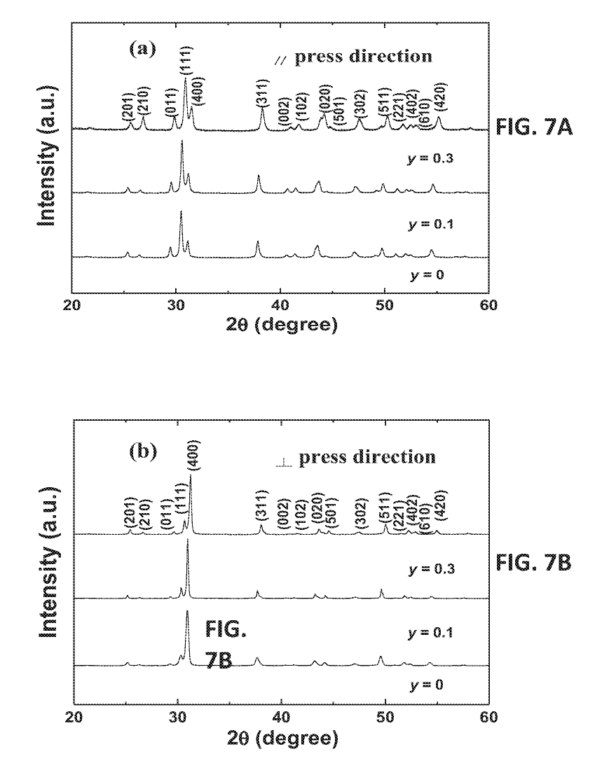

Referring to FIGS. 7A and 7B which illustrate the XRD patterns of alloyed bulk samples SnSe_{0.97-y}S_{y}I_{0.03} (y=0, 0.1, and 0.3) parallel (FIG. 7A) and perpendicular (FIG. 7B) to hot pressing direction. Again strong anisotropy is exhibited in the samples, which is in consistent with the SEM images presented in FIG. 2B. Because SnSe and SnS can form a continuous series of mixed crystals, all the peaks of SnSe_{0.97-y}S_{y}I_{0.03} were indexed to single phase with a minor right shift when SnS is increased.

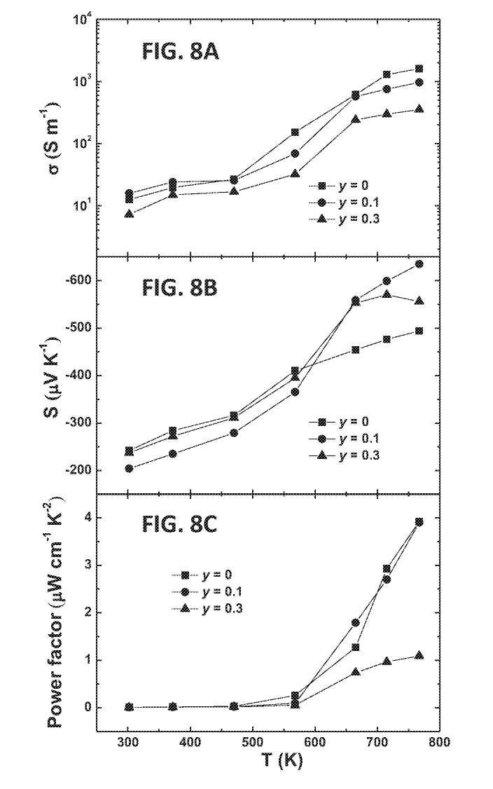

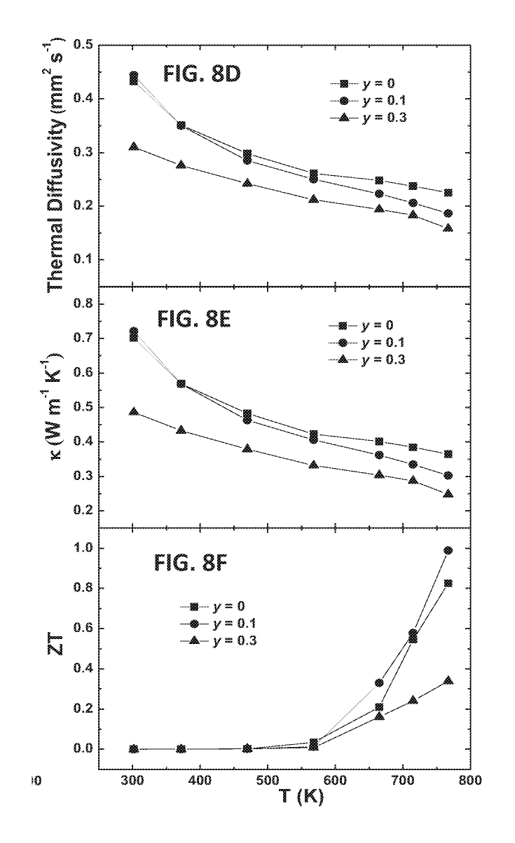

FIGS. 8A-8F are graphs that illustrate the temperature dependence of theremoelectric properties measured parallel to the hot pressing direction of alloyed SnSe_{0.97-y}S_{y}I_{0.03} (y=0.1 and 0.3) compared with SnSe_{0.97}I_{0.03}. In particular, the figures illustrate electrical conductivity (FIG. 8A), Seebeck coefficient (FIG. 8B), power factor (FIG. 8C), thermal diffusivity (FIG. 8D), total thermal conductivity (FIG. 8E) and ZT (FIG. 8F). Both the electrical conductivity (FIG. 8A) and the thermal conductivity (FIG. 8E) decreased with an increasing y value. The Se evaporation was depressed and the electron carrier concentration decreased by introducing S (see table 1). FIG. 8B illustrates the Seebeck coefficient which, at about 775K, is highest for the y=0.1 sample and lowest for the y=0.0.3. The power factor is substantially similar for all three samples from about 300K to about 475K, and substantially similar for the undoped and y=0.1 samples at about 775K, as shown in FIG. 8C. The thermal diffusivity and total thermal conductivity are both highest for the undoped sample and lowest for the y=0.3 sample (FIGS. 8D & 8E), the ZT is above about 0.8 above about 700 K for the y=0.1 sample.

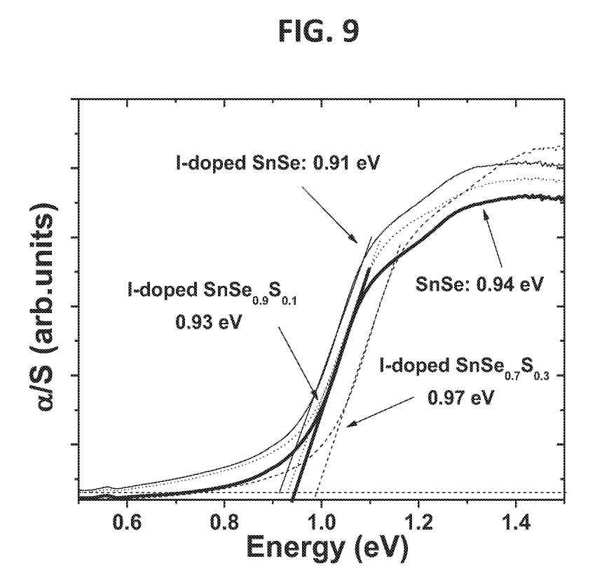

Referring now to FIG. 9, the optical absorption spectra illustrates that the band gap of undoped SnSe is ˜0.94 eV, which is decreased to ˜0.91 eV for SnSe_{0.97}I_{0.03} by I doping and increased to ˜0.97 eV for SnSe_{0.67}S_{0.3}I_{0.03} and ˜0.93 eV for STISe_{0.87}S_{0.1}I_{0.03} by alloying with SnS.

According to the Debye approximation, the theoretical lowest lattice thermal conductivity of the disordered crystals can be calculated as follows,

$${k}_{min} = {( \frac{π}{6} )}^{1 / 3} {κ}_{B} {n}^{2 / 3} {\sum }_{i}^{ } {{v}_{i} ( \frac{T}{{θ}_{i}} )}^{2} {\int }_{0}^{{θ}_{i} / T} \frac{{x}^{3} {e}^{x}}{{( {e}^{x} - 1 )}^{2}} dx \qquad ( 1 )$$

where k_{B} is the Boltzmann constant, n is the atom numbers per volume, vᵢ □_{□} and are the phonon velocity and Debye temperature for three sound modes (two transverse and one longitudinal), respectively. As shown in FIG. 9, the calculated lowest lattice thermal conductivity is ˜0.26 W m⁻¹ K⁻¹ at about 770 K for the low temperature orthorhombic (Pnma) phase SnSe, which is still lower than the experimental results for undoped and I-doped SnSe at 770 K shown in FIG. 4E. So although already having the very low thermal conductivity, alloying with SnS in 3 atm. % iodine-doped SnSe was also employed to further decrease the thermal conductivity. Due to the very low electrical conductivity, the lattice thermal conductivity is also close to the total thermal conductivity (FIG. 8E) which showed a decrease close to the theoretical limit with more alloy scattering. The increased Seebeck coefficient by alloying, together with the lowered thermal conductivity kept the power factor at ˜4 μW cm⁻¹ K⁻² and increased the highest ZT to ˜1.0 at about 773 K for SnSe_{0.87}S_{0.1}I_{0.03}. This finding shows the first n-type Sn chalcogenide alloy also with a desirable peak ZT. However, the low average ZT of tin chalcogenides must be considered.

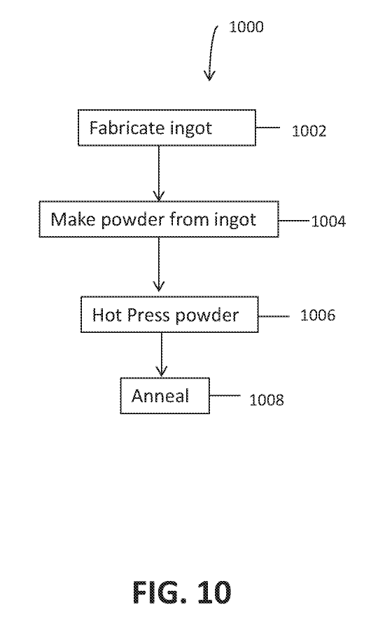

Referring now to FIG. 10, a method 1000 may be employed to fabricate thermoelectric materials according to certain embodiments of the present disclosure by first fabricating an ingot at block 1002. At block 1004, the ingot is broken down into powder by ball-milling or by other manual or automated methods to form powder for hot-pressing at block 1006. In an embodiment, the powder formed comprises particles less than 10 micrometers in diameter. The powder may be hot-pressed at block 1006 to fabricate a thermoelectric chalcogenide comprising a ZT of about 1.0 at above about 770 K. In another embodiment, the pressed component comprises a ZT value of at least 0.80 above about 750 K. It is appreciated that method 1000 is illustrative, and that in some embodiments the process may start at fabricating the ingot at block 1002 by, for example, arc-melting. In other embodiments, the ingot may be pre-fabricated according to the desired composition, and in still other embodiments the powder may be pre-fabricated from an ingot and ready for hot pressing, depending upon the processing parameters and conditions as well as the demand for various products. At block 1008, the pressed component formed at block 1006 may be annealed; it is appreciated that the annealing at block 1008 may not adversely affect the ZT or other thermoelectric properties. In other embodiments, part of the ingot fabrication at block 1002 comprises an annealing/homogenization step. The thermoelectric materials fabricated according to certain embodiments of the present disclosure may be disposed in and/or coupled to various devices for thermoelectric power generation and/or cooling applications as appropriate depending on the application. The devices employing the materials discussed herein may be employed in high temperature applications (e.g., above about 600 K).

Exemplary embodiments are disclosed and variations, combinations, and/or modifications of the embodiment(s) and/or features of the embodiment(s) made by a person having ordinary skill in the art are within the scope of the disclosure. Alternative embodiments that result from combining, integrating, and/or omitting features of the embodiment(s) are also within the scope of the disclosure. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.). For example, whenever a numerical range with a lower limit, R₁, and an upper limit, Rᵤ, is disclosed, any number falling within the range is specifically disclosed. In particular, the following numbers within the range are specifically disclosed: R=R₁+k*(Rᵤ−R₁), wherein k is a variable ranging from 1 percent to 100 percent with a 1 percent increment, i.e., k is 1 percent, 2 percent, 3 percent, 4 percent, 5 percent, . . . , 50 percent, 51 percent, 52 percent, . . . , 95 percent, 96 percent, 97 percent, 98 percent, 99 percent, or 100 percent. Moreover, any numerical range defined by two R numbers as defined in the above is also specifically disclosed. Use of broader terms such as “comprises,” “includes,” and “having” should be understood to provide support for narrower terms such as “consisting of,” “consisting essentially of,” and “comprised substantially of” Each and every claim is incorporated into the specification as further disclosure, and the claims are exemplary embodiment(s) of the present invention.

While exemplary embodiments of the invention have been shown and described, modifications thereof can be made by one skilled in the art without departing from the scope or teachings herein. The embodiments described herein are exemplary only and are not limiting. Many variations and modifications of the compositions, systems, apparatus, and processes described herein are possible and are within the scope of the invention. Accordingly, the scope of protection is not limited to the embodiments described herein, but is only limited by the claims that follow, the scope of which shall include all equivalents of the subject matter of the claims. Unless expressly stated otherwise, the steps in a method claim may be performed in any order and with any suitable combination of materials and processing conditions.

1. A method of manufacturing a thermoelectric material comprising:
hot-pressing a powder in a predetermined direction to form a pressed component, wherein the powder comprises Sn and Se,
wherein the pressed component comprises a ZT value of at least 0.8 above about 750 K.

2. The method of claim 1, further comprising, prior to hot-pressing, forming the powder from an ingot by ball-milling.

3. The method of claim 2, further comprising annealing the ingot prior to ball-milling.

4. The method of claim 1, wherein the powder further comprises iodine (I).

5. The method of claim 4, wherein the ingot is fabricated according to the formula SnSe₁₋ₓIₓ, wherein x is from about 0.005 to about 0.5.

6. The method of claim 4, wherein the powder further comprises sulfur (S).

7. The method of claim 4, wherein the ingot is fabricated according to the formula SnSe_{1-x-y}S_{y}Iₓ.

8. The method of claim 7, wherein x is from about 0.005 to about 0.05.

9. The method of claim 7, wherein y is from about 0.05 to about 0.5.

10. The method of claim 1, further comprising annealing the pressed component.

11. A thermoelectric device comprising:
a thermoelectric material according to a formula SnSe₁₋ₓIₓ,
wherein the thermoelectric material comprises a ZT of at least 0.8 at about 750 K.

12. The thermoelectric device of claim 11, wherein the thermoelectric material comprises a plurality of grains formed by is hot-pressing a powder according to the formula SnSe₁₋ₓIₓ in a predetermined direction, and wherein the ZT is at least 0.8 at about 750 K as measured in a direction parallel to the predetermined direction.

13. The thermoelectric device of claim 11, wherein x is from about 0.005 to about 0.5.

14. The thermoelectric device of claim 11, wherein x is from about 0.2 to about 0.4.

15. A thermoelectric device comprising:
a thermoelectric material according to the formula SnSe_{1-x-y}S_{y}Iₓ wherein the thermoelectric material comprises a ZT of at least 0.8 at above about 750 K.

16. The thermoelectric device of claim 15, wherein the thermoelectric material is hot-pressed in a predetermined direction, and wherein the ZT is at least 0.8 at about 750 K as measured in a direction parallel to the predetermined direction.

17. The thermoelectric device of claim 15, wherein x is from about 0.005 to about 0.05.

18. The thermoelectric device 1 of claim 15, wherein x is about 0.03.

19. The thermoelectric device of claim 18, wherein the thermoelectric material comprises a ZT of above about 1.0 above about 750 K.

20. The thermoelectric device of claim 13, wherein y is from about 0.05 to about 0.5.
